(19) United States
(12) Patent Application Publication
(10) Pub. No.: US 2025/0316310 A1
(43) Pub. Date: Oct. 9, 2025

(54) MEMORY CELL

(71) Applicants: TAIWAN SEMICONDUCTOR MANUFACTURING COMPANY, LTD., Hsinchu (TW); NATIONAL TAIWAN UNIVERSITY, TAIPEI (TW)

(72) Inventors: Kuo-Yu HSIANG, Kaohsiung City (TW); Min-Hung LEE, New Taipei City (TW)

(73) Assignees: TAIWAN SEMICONDUCTOR MANUFACTURING COMPANY, LTD., Hsinchu (TW); NATIONAL TAIWAN UNIVERSITY, TAIPEI (TW)

(21) Appl. No.: 18/791,999

(22) Filed: Aug. 1, 2024

Related U.S. Application Data
(60) Provisional application No. 63/573,637, filed on Apr. 3, 2024.

(51) Int. Cl. G11C 13/00; H10B 63/00; H10N 70/00

(52) U.S. Cl. CPC G11C 13/0069; G11C 13/004; H10B 63/30; H10N 70/841; H10N 70/8833

(57) ABSTRACT

A memory cell includes a substrate, a bottom electrode over the substrate, a variable resistance film over the bottom electrode, and a top electrode over the variable resistance film. The variable resistance film exhibits a first polarization in response to a first voltage sweep operation within a first voltage range, exhibits a second polarization in response to a second voltage sweep operation within a second voltage range, and exhibits a third polarization in response to a third voltage sweep operation within a third voltage range, wherein the first voltage range, the second voltage range, and the third voltage range are different from one another.

### CROSS REFERENCE

This application claims priority to U.S. Provisional Patent Application Ser. No. 63/573,637, filed Apr. 3, 2024, which is herein incorporated by reference in its entirety.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs and, for these advancements to be realized, similar developments in IC processing and manufacturing are needed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a memory cell in accordance with some embodiments.

FIG. 2 is a semiconductor device including the memory cell according to some embodiments of the present disclosure.

FIG. 3A shows polarization responses of the memory cell by performing multiple voltage sweep operations in accordance with some embodiments.

FIG. 3B shows the multiple voltage sweep operations including a first voltage sweep operation, a second voltage sweep operation and a third voltage sweep operation.

FIG. 3C shows a flowchart of operating the memory cell using the multiple voltage sweep operations in FIG. 3A in accordance with some embodiments.

FIG. 4A is a diagram showing dipoles switching speed responses under the first voltage sweep operation and the third voltage sweep operation of the memory cell in FIG. 1 in accordance with some embodiments.

FIG. 4B is a diagram showing dipoles switching speed responses under the second voltage sweep operation of the memory cell in accordance with some embodiments.

FIG. 5 is a chart of normalized polarization (ΔPr) of switching cycling with respect of the memory cell in FIG. 1 in accordance with some embodiments.

FIG. 6A is a diagram showing cycling the memory cell in FIG. 1 by using the first voltage sweep operation (i.e., the first voltage sweep operation in FIG. 3B) without cycling using the second and third operations (i.e., the second voltage sweep operation and the third voltage sweep operation in FIG. 3B) in accordance with some embodiments.

FIG. 6B is a diagram showing cycling the memory cell in FIG. 1 by using the second voltage sweep operation (i.e., the second voltage sweep operation in FIG. 3B) without cycling using the first and third operations (i.e., the first voltage sweep operation and the third voltage sweep operation in FIG. 3B) in accordance with some embodiments.

FIG. 6C is a diagram showing cycling the memory cell in FIG. 1 by using the third voltage sweep operation (i.e., the third voltage sweep operation in FIG. 3B) without cycling using the first and second operations (i.e., the first voltage sweep operation and the second voltage sweep operation in FIG. 3B) in accordance with some embodiments.

FIG. 7A shows polarization-voltage (P-V) characteristic with regard to the memory cell in FIG. 1 in accordance with some embodiments.

FIG. 7B is a chart of normalized polarization (Δ2Pr) versus retention time using the access voltage of small value (e.g., about −1.5 V to about 1.5V) with respect of the memory cell in FIG. 1, which corresponds to the third loop in FIG. 7A, in accordance with some embodiments.

FIGS. 8-9, 10A, and 11-16 illustrate schematic cross-sectional views of a memory cell at various stages of fabrication in accordance with some embodiments of the present disclosure.

FIG. 10B illustrates an enlarged cross-sectional view of the variable resistance film of FIG. 10A in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. As used herein, “around,” “about,” “approximately,” or “substantially” may mean within 20 percent, or within 10 percent, or within 5 percent of a given value or range. Numerical quantities given herein are approximate, meaning that the term “around,” “about,” “approximately,” or “substantially” can be inferred if not expressly stated.

Antiferroelectric random access memory (AFERAM) as main memory has latency and energy consumption of data transmission issues. AFERAM has only two stable bits per cell as volatile memory. As storage class memory, ferroelectric random access memory (FERAM) has only one stable bit per cell as non-volatile memory and has slow access speed.

The present disclosure provides an operation method to the memory cell to combine volatile FERAM and non-volatile AFERAM within a complementary-dynamic random access memory (C-DRAM) in one cell. Data transmission latency and energy consumption between main memory (e.g., DRAM) and storage class memory (SCM) of the memory hierarchy can be eliminated. Dual functionalities (e.g., volatile and non-volatile) of the single C-DRAM in the one cell can retain advantages of stable data retention of FERAM and rapid speed access of AFERAM. The C-DRAM has 3-bit multilevel states, and the 3-bit multilevel states can exhibit independent polarities on fatigue.

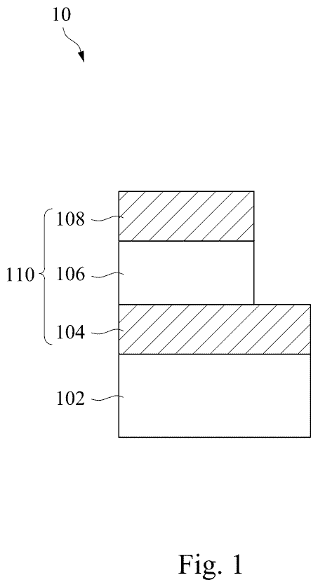

FIG. 1 illustrates a memory cell 10 in accordance with some embodiments. The memory cell 10 may include a substrate 102, a bottom electrode 104, a variable resistance pattern 106 and a top electrode 108, which are sequentially stacked. In other words, the bottom electrode 104, the variable resistance pattern 106 and the top electrode 108 are stacked in sequence. The bottom electrode 104, the variable resistance pattern 106 and the top electrode 108 constitute a capacitor 110 for storing memory data. The bottom electrode 104 and the top electrode 108 are formed of, for example, a conductive material such as metal, alloy, a compound thereof, or a stack of metal, alloy, the compound thereof. Examples of the bottom electrode 104 and the top electrode 108 include suitable conductive materials, such as TaN, TIN, W, Pt, Mo, Ta, Ti, metal silicide, the like, and/or the combination thereof. The bottom electrode 104 and the top electrode 108 can be a single-layered structure or a multi-layered structure including plural stacked layers of metals and/or metal-containing compounds. In some embodiments, the bottom electrode 104 and the top electrode 108 each have a thickness in a range from about 1 nm to about 1000 nm, such as about 1 nm to about 100 nm, such as about 50 nm.

In some embodiment, the variable resistance pattern 106 is a ferroelectric layer. In some embodiments, the variable resistance pattern 106 may include HfZrO₂ (HZO), HAO (Al-Doped HfO₂), HSO (Si-Doped HfO₂), HLO (La-Doped HfO₂), lead zirconate titanate (PZT), strontium bismuth tantalit (SBT), aluminum scandium nitride (AlScN), or a combination thereof. The variable resistance pattern 106 can be made of Hf₁₋ₓZrₓO₂ in which x is from 0.5 to 1. In some embodiments, the variable resistance pattern 106 has a thickness in a range from about 0.1 nm to about 50 nm, such as about 10 nm. In use and operation, when the memory cell 10 is selected to be programmed, a programming voltage may be applied to the memory cell 10 to change a polarization state of the variable resistance pattern 106 of the memory cell 10.

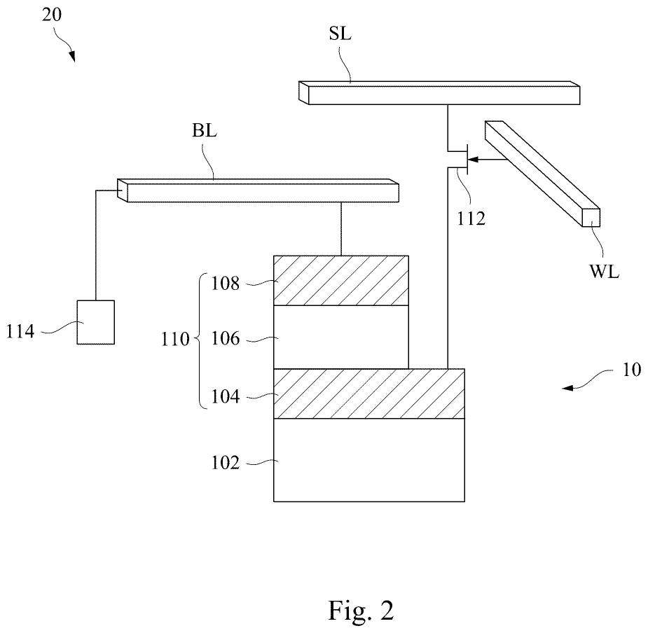

FIG. 2 is a semiconductor device 20 including the memory cell 10 according to some embodiments of the present disclosure. The semiconductor device 20 includes the memory cell 10 including the capacitor 110, an access transistor 112, a conductive line BL that may function as a data line (e.g., a bit line), a conductive line WL that may function as an access line (e.g., a word line), a conductive line SL that may function as a source line, and a periphery device 114 such as a read/write circuitry. To initiate programming of the memory cell 10, the periphery device 114 may generate a programming voltage to the conductive line BL and the conductive line SL. The polarity of the voltage between the conductive line BL and the conductive line SL may determine the polarization direction of the variable resistance pattern 106 in the capacitor 110. The programmed logic state of the memory cell 10 may be a function of the direction of polarization of the variable resistance pattern 106 of the capacitor 110. To read the memory cell 10, the periphery device 114 may generate a read voltage to the conductive line BL and the conductive line SL through the capacitor 110 and the access transistor 112. The programmed state of the memory cell 10 may be related to a direction of the polarization of the variable resistance pattern 106 in the capacitor 110.

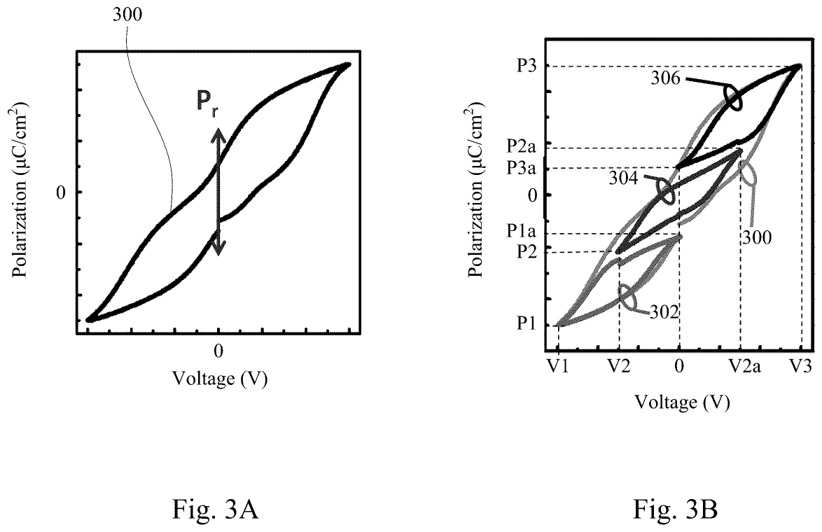

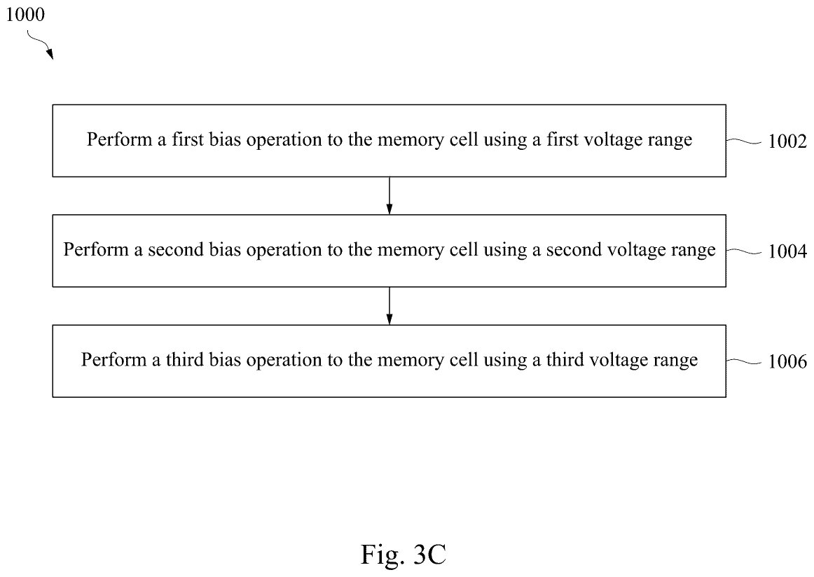

FIG. 3A shows polarization responses of the memory cell 10 by performing multiple voltage sweep operations in accordance with some embodiments. The multiple voltage sweep operations in FIG. 3A can be subdivided into 3-bit multilevel memory operations, as shown in FIG. 3B. FIG. 3B shows the multiple voltage sweep operations including a first voltage sweep operation 302, a second voltage sweep operation 304 and a third voltage sweep operation 306. The first voltage sweep operation 302, the second voltage sweep operation 304 and the third voltage sweep operation 306 can be collectively shown as a loop 300. In FIG. 3A, at zero field strength, magnetization is offset from an origin by a remanence Pr. FIG. 3C shows a flowchart of a method 1000 of operating the memory cell 10 using the multiple voltage sweep operations in FIG. 3A in accordance with some embodiments. The method 1000 includes a relevant part of an entire operation. It is understood that additional operations may be provided before, during and after the operations shown by FIG. 3C, and some of the operations described below can be replaced or eliminated for additional embodiments of the method 1000. The order of the operations/processes may be interchangeable. Reference is made to FIG. 3C. The method 1000 begins at an operation 1002 in which the operation 1002 includes performing a first voltage sweep operation to the memory cell using a first voltage range. Reference is made to FIGS. 3B and 3C. In some embodiments of the operation 1002, a first voltage sweep operation 302 is performed to the memory cell 10 using a first voltage range in a range from a voltage V1 to zero. The first voltage sweep operation 302 is a unipolar voltage sweep operation. In other words, the first voltage sweep operation 302 can be performed such that the variable resistance pattern 106 is in a program state and in an erase state based on one or more electrical signals that are of the same polarity. In some embodiments, the first voltage sweep operation 302 can be a negative unipolar loop. In other words, the first voltage sweep operation 302 can be performed such that the variable resistance pattern 106 is both programmed and erased from electrical signals that comprise the negative polarity. For example, the memory cell 10 once initially programmed, can be later erased in response to a first non-positive voltage and programmed in response to second non-positive voltage. That is, the first voltage sweep operation 302 is performed using a negative voltage range. For example, the negative voltage range is from a negative voltage to zero. In other words, the first voltage sweep operation 302 is performed using a voltage range that is not positive. In some embodiments, a constant base voltage (V_{base}) is provided to retain an information of the memory cell 10, and a write voltage is applied to switch a polarization to the low resistance state (LRS) by applying a programming voltage (Vₚ) (i.e., the voltage V1 in FIG. 3B), such as about −3V, greater than the constant base voltage (V_{base}) or to the high resistance state (HRS) by applying a programming voltage (Vₚ) equal to zero. In some embodiments, a constant base voltage (V_{base}) is about −1 V.

Reference is made to FIG. 3C. The method 1000 proceeds to operation 1004 in which the operation 1004 includes performing a second voltage sweep operation to the memory cell 10 using a second voltage range. Reference is made to FIGS. 3B and 3C. In some embodiments of the operation 1004, a second voltage sweep operation 304 is performed to the memory cell 10 using a second voltage range in a range from a voltage V2 to a voltage V2a. The second voltage sweep operation 304 is a bipolar operation. In other words, the second voltage sweep operation 304 can be performed such that the variable resistance pattern 106 is in a program state and in an erase state based on one or more electrical signals that are of different polarities. For example, the second voltage sweep operation 304 is a bipolar loop. That is, the second voltage sweep operation 304 is performed using a voltage range comprising a positive voltage and a negative voltage. In other words, the voltage rang is from a negative voltage to a positive voltage. In some embodiments, a constant base voltage (V_{base}) is provided to retain an information of the memory cell 10, and a write voltage is applied to switch a polarization by applying a programming voltage (Vₚ) (i.e., the voltage V2 in FIG. 3B), such as about −1.5V, greater than the constant base voltage (V_{base}) or by applying a programming voltage (Vₚ) (i.e., the voltage V2a in FIG. 3B), such as about 1.5V, greater than the constant base voltage (V_{base}). In some embodiments, a constant base voltage (V_{base}) is about 0 V.

Reference is made to FIG. 3C. The method 1000 proceeds to operation 1006 in which the operation 1006 includes performing a third voltage sweep operation to the memory cell 10 using a third voltage range. Reference is made to FIGS. 3B and 3C. In some embodiments of the operation 1006, a third voltage sweep operation 306 is performed to the memory cell 10 using a third voltage range in a range from zero to a voltage V3. The third voltage sweep operation 306 is a unipolar voltage sweep operation. In other words, the first voltage sweep operation 302 can be performed such that the variable resistance pattern 106 is in a program state and in an erase state based on one or more electrical signals that are of the same polarity. In some embodiments, the third voltage sweep operation 306 can be a positive unipolar loop. In other words, the third voltage sweep operation 306 can be performed such that the variable resistance pattern 106 is both programmed and erased from electrical signals that comprise the positive polarity. For example, the memory cell 10 once initially programmed, can be later erased in response to a first non-negative voltage and programmed in response to second non-negative voltage. That is, the third voltage sweep operation 306 is performed using a positive voltage range. For example, the positive voltage range is from zero to a positive voltage. In other words, the third voltage sweep operation 306 is performed using a voltage range that is not negative. In some embodiments, a constant base voltage (V_{base}) is provided to retain the information of the memory cell 10, and the write voltage is applied to switch the polarization to the low resistance state (LRS) by applying a programming voltage (Vₚ) (i.e., the voltage V3 in FIG. 3B), such as about 3V, greater than the constant base voltage (V_{base}) or to the high resistance state (HRS) by applying a programming voltage (Vₚ) equal to zero. In some embodiments, a constant base voltage (V_{base}) is about 1 V. Referring back to FIGS. 1 and 3B, in some embodiments, the first voltage sweep operation 302 is performed such that the variable resistance pattern 106 has first polarizations P1 or P1a. In some embodiments, the second voltage sweep operation 304 is performed such that the variable resistance pattern 106 has second polarizations P2 or P2a. In some embodiments, the third voltage sweep operation 306 is performed such that the variable resistance pattern 106 has third polarizations P3 or P3a. The first polarization P1, the second polarization P2 and the third polarization P3a can be different from one another in quantities. The first polarization P1a, the second polarization P2a and the third polarization P3 can be different from one another in quantities. The first polarizations P1, P1a and the second polarization P2 can be negative. The second polarization P2a and the third polarizations P3, P3a can be positive.

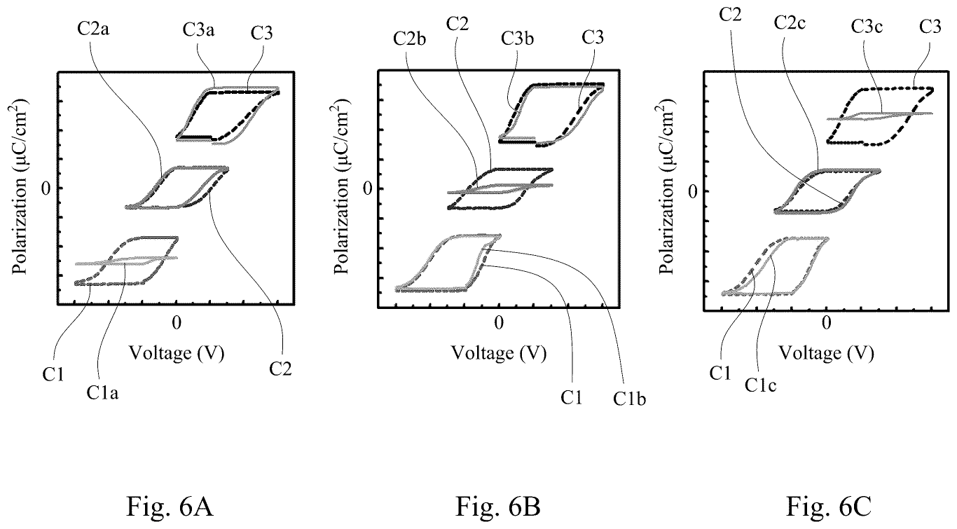

Voltage ranges of corresponding first voltage sweep operation 302, the second voltage sweep operation 304 and the third voltage sweep operation 306 non-overlaps with one another. In some embodiments, the memory cell 10 is cycled by applying the first voltage sweep operation 302, the second voltage sweep operation 304 and the third voltage sweep operation 306 alternately. For example, after applying the first voltage sweep operation 302, the second voltage sweep operation 304 or the third voltage sweep operation 306 is applied to the memory cell 10. Similarly, after applying the second voltage sweep operation 304, the first voltage sweep operation 302 or the third voltage sweep operation 306 is applied to the memory cell 10. Similarly, after applying the third voltage sweep operation 306, the first voltage sweep operation 302 or the second voltage sweep operation 304 is applied to the memory cell 10. Because the memory cell 10 is operated using different operated loops, degradation in Positive Up Negative Down (PUND) loop due to cycling of the same operated loop can thus be prevented, which will be discussed in greater details in FIGS. 6A-6C. In some embodiments, the memory cell 10 can be cycled by writing the first voltage range of the first voltage sweep operation 302, the second voltage range of the second voltage sweep operation 304 and the third voltage range of the third voltage sweep operation 306 in sequence.

The first voltage sweep operation 302 and the third voltage sweep operation 306 can store a variable amount of charge in a volatile manner. The third voltage sweep operation can store a variable amount of charge in a non-volatile manner so that the stored charge persists in the absence of power. In the non-volatile manner, when the programming voltage is removed, the variable resistance pattern 106 may exhibit a polarization. In a read operation of the memory cell 10, a voltage is used to detect a state of the variable resistance pattern 106. Such dual functionalities (i.e., volatile and non-volatile) of the single C-DRAM (i.e., one memory cell 10) can retain advantage of stable data retention of non-volatile memory (or FERAM) and advantage of rapid speed access of volatile memory (or AFERAM). Combination of the volatile and non-volatile memory within the single C-DRAM (i.e., one memory cell 10) can eliminate data transmission latency and energy consumption between the main memory system (DRAM) and storage class memory (SCM) of the memory hierarchy.

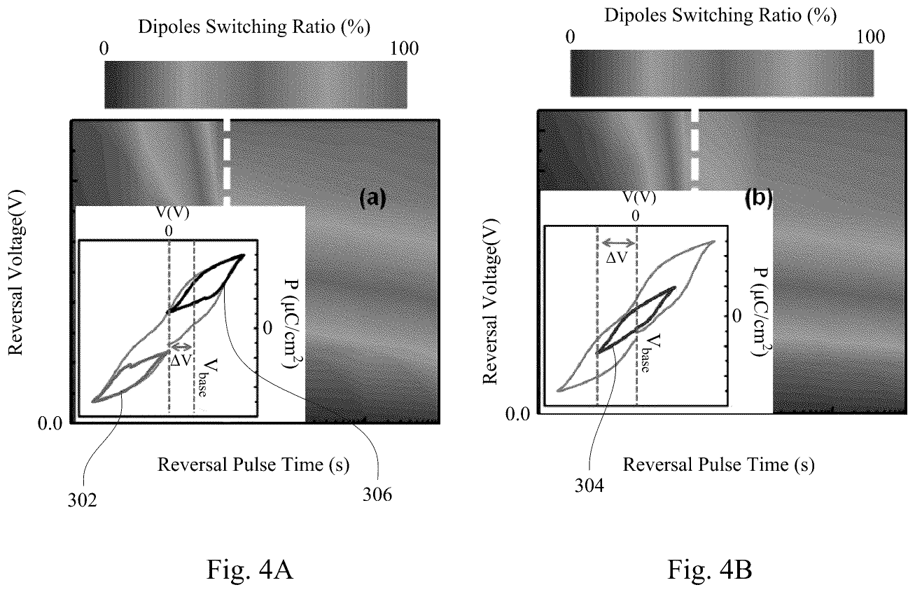

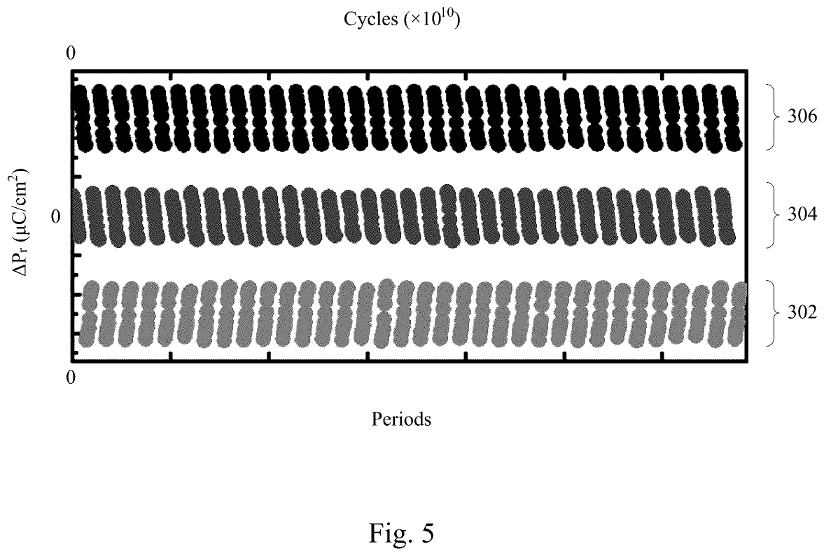

FIG. 4A is a diagram showing dipoles switching speed responses under the first voltage sweep operation and the third voltage sweep operation of the memory cell 10 in FIG. 1 in accordance with some embodiments. FIG. 4B is a diagram showing dipoles switching speed responses under the second voltage sweep operation of the memory cell 10 in accordance with some embodiments. Referring to FIG. 4A, the first voltage sweep operation and the third voltage sweep operation of the memory cell 10, which are used as volatile memory, are dominated by tetragonal phase (t-phase). A programming voltage in which difference between the constant base voltage (V_{base}) is ΔV is applied in the third voltage sweep operation. Referring to FIG. 4B, the second voltage sweep operation, which is used as non-volatile memory, of the memory cell 10 is dominated by orthogonal phase (o-phase). A programming voltage in which difference between the constant base voltage (V_{base}) is ΔV is applied in the second voltage sweep operation. With reference to FIGS. 4A and 4B. With reversal pulse time less than about 1 μs, the first voltage sweep operation 302 and the third voltage sweep operation 306 each have an available ratio higher than an available ratio of the second operation due to the t-phase having a switching speed faster than a switching speed of the o-phase.

FIG. 5 is a chart of normalized polarization (ΔPr) of switching cycling with respect of the memory cell 10 in FIG. 1 in accordance with some embodiments. Reference is made to FIG. 5. The memory cell 10 is cycled using the first voltage sweep operation, the second voltage sweep operation and the third voltage sweep operation as discussed previously with regard to FIG. 3B in an alternate manner. The memory cell 10 shows long endurance characteristics of dual functionalities (that is, volatile and non-volatile characteristics) of the C-DRAM. For example, the memory cell demonstrates about 10¹¹ to about 10¹³ switching cycles, such as about 1.02×10¹² switching cycles.

FIG. 6A is a diagram showing cycling the memory cell 10 in FIG. 1 by using the first voltage sweep operation (i.e., the first voltage sweep operation 302 in FIG. 3B) without cycling using the second and third operations (i.e., the second voltage sweep operation 304 and the third voltage sweep operation 306 in FIG. 3B) in accordance with some embodiments. Dashed loop C1, C2, C3 refer to first cycles of the first voltage sweep operation, second voltage sweep operation and third voltage sweep operation, respectively. Solid loops C2a, C3a refer to P-V characteristics of the non-cycled second voltage sweep operation 304 and the third voltage sweep operation 306 at about 10⁹th cycle after cycling about 10⁹ cycles using the first voltage sweep operation 302. Solid loop C1a refers to the memory cell 10 after cycling about 10⁹ cycles of the first voltage sweep operation. Degradation occurs in the first voltage sweep operation 302 while non-cycled second voltage sweep operation 304 and the third voltage sweep operation 306 maintain an initial state. This indicates independence for the first operation 302, the second operation 304 and the third operation 306. That is, for the memory cell 10, 3-bit multilevel states are independent form one other.

FIG. 6B is a diagram showing cycling the memory cell 10 in FIG. 1 by using the second voltage sweep operation (i.e., the second voltage sweep operation 304 in FIG. 3B) without cycling using the first and third operations (i.e., the first voltage sweep operation 302 and the third voltage sweep operation 306 in FIG. 3B) in accordance with some embodiments. Dashed loop C1, C2, C3 refer to first cycles of the first voltage sweep operation, second voltage sweep operation and third voltage sweep operation, respectively. Solid loops C1b, C3b refer to P-V characteristics of the non-cycled first voltage sweep operation 302 and the third voltage sweep operation 306 at about 10⁹th cycle after cycling about 10⁹ cycles using the first voltage sweep operation 302. Solid loop C2a refers to the memory cell 10 after cycling about 10⁹ cycles of the second voltage sweep operation. Degradation occurs in the second voltage sweep operation 304 while non-cycled first voltage sweep operation 302 and the third voltage sweep operation 306 maintain an initial state. This indicates independence for the first operation 302, the second operation 304 and the third operation 306. That is, for the memory cell 10, 3-bit multilevel states are independent form one other.

FIG. 6C is a diagram showing cycling the memory cell 10 in FIG. 1 by using the third voltage sweep operation (i.e., the third voltage sweep operation 306 in FIG. 3B) without cycling using the first and second operations (i.e., the first voltage sweep operation 302 and the second voltage sweep operation 304 in FIG. 3B) in accordance with some embodiments. Dashed loop C1, C2, C3 refer to first cycles of the first voltage sweep operation, second voltage sweep operation and third voltage sweep operation, respectively. Solid loops C1c, C2c refer to P-V characteristics of the non-cycled first voltage sweep operation 302 and the second voltage sweep operation 304 at about 10⁹th cycle after cycling about 10⁹ cycles using the first voltage sweep operation 302. Solid loop C3a refers to the memory cell 10 after cycling about 10⁹ cycles of the third voltage sweep operation. Degradation occurs in the third voltage sweep operation 306 while non-cycled first voltage sweep operation 302 and the second voltage sweep operation 304 maintain an initial state. This indicates independence for the first operation 302, the second operation 304 and the third operation 306. That is, for the memory cell 10, 3-bit multilevel states are independent form one other.

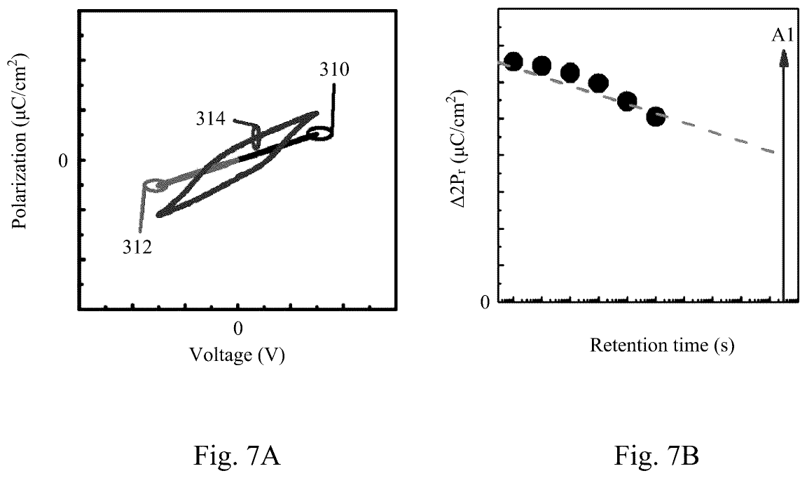

FIG. 7A shows polarization-voltage (P-V) characteristic with regard to the memory cell 10 in FIG. 1 in accordance with some embodiments. Reference is made to FIG. 7A. First loop 310 shows operating the memory cell 10 using an access voltage such as about 0V and about 1.5V. That is, the first loop 310 is a positive unipolar loop. The first loop 310 exhibits paraelectric characteristic. Second loop 312 shows operating the memory cell 10 using an access voltage such as about 0V and about −1.5V. That is, the second loop 312 is a negative unipolar loop. The second loop 312 exhibits paraelectric characteristic. The third loop 314 is similar to the second voltage sweep operation in FIG. 3B. That is, the third loop 314 is operated using a programming voltage such as about −1.5V and about 1.5V. Compared to the first loop 310 and the second loop 312, the third loop 314 is a bipolar loop and exhibits ferroelectric characteristic. Therefore, the ferroelectric characteristic is within the small access voltage range (e.g., about −1.5 V to about 1.5V). As discussed previously with regard to FIG. 4B, the ferroelectric characteristic is dominated by orthogonal phase.

FIG. 7B is a chart of normalized polarization (Δ2Pr) versus retention time using the access voltage of small value (e.g., about −1.5 V to about 1.5V) with respect of the memory cell 10 in FIG. 1, which corresponds to the third loop 314 in FIG. 7A, in accordance with some embodiments. Reference is made to FIG. 7B. Using the access voltage of small value can exhibit stable data retention used as non-volatile memory. For example, the data retention is greater than about 10⁴ seconds and is with extrapolation to about 10 years (indicated as an arrow Al).

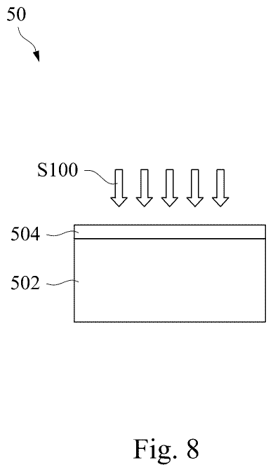

FIGS. 8-9, 10A, and 11-16 illustrate schematic cross-sectional views of a memory cell 50 at various stages of fabrication in accordance with some embodiments of the present disclosure. It is understood that additional operations may be provided before, during, and after the operations shown by FIGS. 8-16, and some of the operations described below can be replaced or eliminated for additional embodiments of the method. The order of the operations/processes may be interchangeable.

Reference is made to FIG. 8. A substrate 502 is provided. The substrate 502 may include transistors and one or more interconnect layers formed thereon. The substrate 502 may be a semiconductor substrate, such as silicon substrate. Alternatively, the substrate 502 may include another elementary semiconductor, such as germanium; a compound semiconductor including silicon carbide; an alloy semiconductor including silicon germanium; or combinations thereof. The substrate 502 may include group-IV semiconductor materials, III-V compound semiconductor materials, transition-metal dichalcogenides (TMD). In some embodiments, the substrate 502 is a semiconductor on insulator (SOI) substrate. The substrate 502 may include doped regions, such as p-wells and n-wells. The transistors are formed by suitable transistor fabrication processes and may be a planar transistor, such as polysilicon gate transistors or high-k metal gate transistors, or a multi-gate transistor, such as fin field effect transistors. After the transistors are formed, one or more interconnect layers of a multi-level interconnect (MLI) is formed over the transistors.

As the substrate 502 is exposed to air under ambient conditions, a native oxide layer 504 is formed on the substrate 502. In some embodiments, when the substrate 502 comprises silicon, the native oxide layer 504 may be a thin layer of SiO₂. The substrate 502 is subjected to a cleaning process S100 for removing the native oxide layer 504 from the top surface of the substrate 502. The cleaning process may include using suitable cleaning agent, such as diluted water, HF, the like. In some embodiments, the cleaning process S100 is performed in a duration from about 50 s to about 70 s, such as about 60 s.

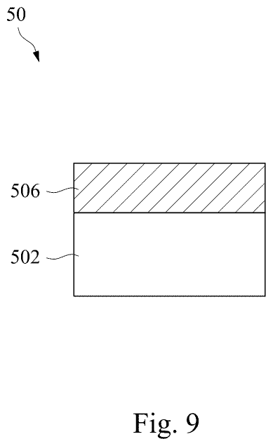

Reference is made to FIG. 9. A bottom electrode layer 506 is deposited over the substrate 502. In some embodiments, the bottom electrode layer 506 may include suitable conductive materials, such as TaN, TiN, W, Pt, Ni, Mo, Ta, Ti, Ru, metal silicide, the like, or a combination thereof. The bottom electrode layer 506 can be a single-layered structure or a multi-layered structure including plural stacked layers of metals and/or metal-containing compounds. The bottom electrode layer 506 may be exemplarily formed by CVD, PVD (e.g., sputtering deposition), atomic layer deposition (ALD), the like, or other suitable methods. In some embodiments, the bottom electrode layer 506 may have a thickness in a range from about 1 nm to about 1000 nm. In some other embodiments, the bottom electrode layer 506 may have other suitable thickness. In some embodiments, the bottom electrode layer 506 includes a thickness in a range from about 1 nm to about 100 nm, such as about 50 nm.

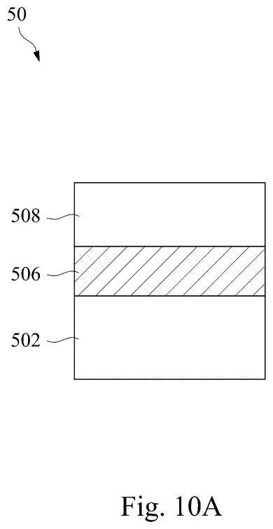

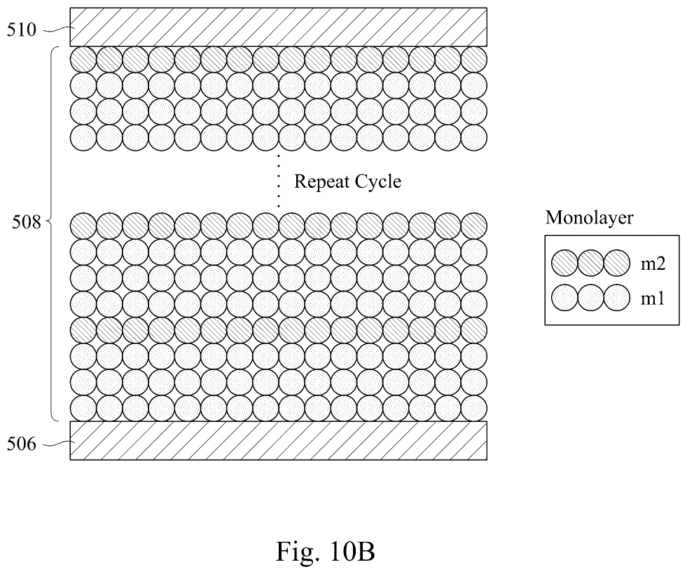

Reference is made to FIG. 10A. A variable resistance film 508 is deposited over the bottom electrode layer 506. In some embodiments, the variable resistance film 508 may include hafnium zirconium oxide (HZO), aluminum-doped hafnium oxide (HAO), silicon-doped hafnium oxide (HSO), lead zirconate titanate (PZT), strontium bismuth tantalite (SBT), the like, or a combination thereof. In the embodiments where the variable resistance film 508 includes HZO, the variable resistance film 508 may include Hf₁₋ₓZrₓO₂, in which x may be greater than 50% and less than 100%. Stated differently, a ratio of a Zr content to a sum of Zr content and Hf content in HZO is greater than 50% and less than 100%. For example, the variable resistance film 508 may include Hf_{0.25}Zr_{0.75}O₂. The variable resistance film 508 can be a ferroelectric layer, an anti-ferroelectric layer, a multilayer stack of ferroelectric layer and dielectric layer, or a multilayer stack of antiferroelectric layer and dielectric layer. The dielectric layer can be SiO₂, Al₂O₃, HfO₂, ZrO₂, TiO₂, Ta₂O₃. WO₃, the like, or a combination thereof, with a thickness in a range from about 0.1 nm to about 10 nm. In some embodiments, the variable resistance film 508 can have a t-phase, an o-phase, or a combination thereof.

The variable resistance film 508 may be formed by an ALD process or a PVD process. For example, the variable resistance film 508 is deposited with a thickness in a range from about 0.1 nm to about 50 nm in some embodiments. In some embodiments, the variable resistance film 508 includes a thickness in a range from about 5 nm to about 15 nm, such as about 10 nm. In some embodiments, the variable resistance film 508 has a tetragonal structure, an orthorhombic structure or a combination thereof.

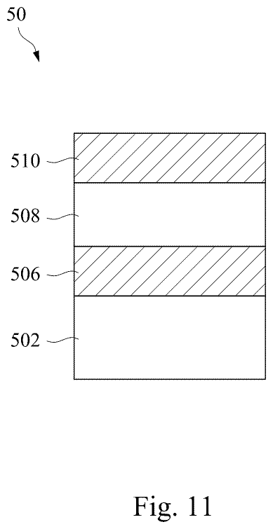

FIG. 10B illustrates an enlarged cross-sectional view of the variable resistance film 508 of FIG. 10A in accordance with some embodiments of the present disclosure. In some embodiments where the variable resistance film 508 is formed by ALD, the variable resistance film 508 can be formed by repeating a plurality of deposition cycles and include a thickness in a range from about 5 nm to about 15 nm, such as about 10 nm. The deposition cycles each include forming a plurality of first monolayers m1 and a second monolayer m2 after forming the plurality of first monolayers m2. In some embodiments, the monolayers m1 can be ZrO₂, and the monolayer m2 can be HfO₂, resulting formation of Hf_{0.25}Zr_{0.75}O₂. After forming the variable resistance film 508, a top electrode layer 510 is deposited over the variable resistance film 508. Reference is made to FIG. 11. The top electrode layer 510 is deposited over the variable resistance film 508. In some embodiments, the top electrode layer 510 may include suitable conductive materials, such as TaN, TiN, W, Pt, Ni, Mo, Ta, Ti, Ru, metal silicide, the like, or a combination thereof. The top electrode layer 510 can be a single-layered structure or a multi-layered structure including plural stacked layers of metals and/or metal-containing compounds. The top electrode layer 510 may be exemplarily formed by chemical vapor deposition (CVD), PVD (e.g., sputtering deposition), ALD, the like, or other suitable methods. In some embodiments, the top electrode layer 510 has a thickness in a range from about 1 nm to about 1000 nm. In some other embodiments, the top electrode layer 510 may have other suitable thickness. The top electrode layer 510 may include a conductive material the same as or different from that of the bottom electrode layer 506. In some embodiments, the top electrode layer 120 includes a thickness in a range from about 1 nm to about 100 nm, such as about 50 nm.

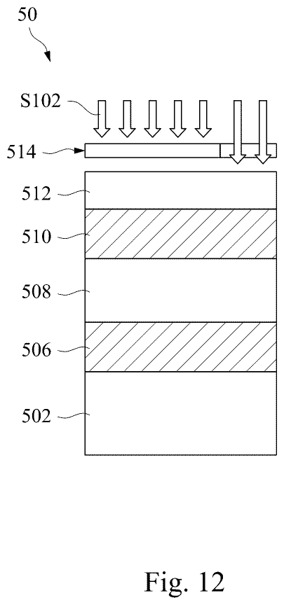

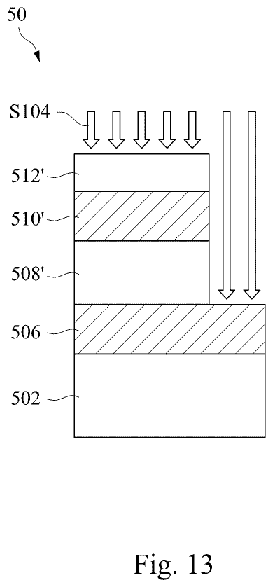

Reference is made to FIG. 12. A resist layer 512 is formed over the top electrode layer 510. In some embodiments, the resist layer 512 is an ashing removable dielectric (ARD), which is a photoresist-like material having the properties of a photoresist and amendable to etching and patterning like a photoresist. The resist layer 512 may also act as a mask layer for patterning underlying layers in some embodiments. The resist layer 512 may be formed by spin-on coating. In some embodiments, an exposure apparatus including a light source and a mask 514 is used for providing light S102 for exposing the resist layer 512. The resist layer 512 may be patterned using suitable photolithography process, thereby forming the variable resistance pattern 508′ (referring to FIG. 13). For example, the process may include photoresist coating (e.g., spin-on coating), soft baking, mask aligning, exposure, post-exposure baking, developing the photoresist, rinsing, drying (e.g., hard baking), other suitable processes, or combinations thereof.

Reference is made to FIG. 13. One or more etching processes S104 are performed to etch portions of the films/layers 508, 510 (referring to FIG. 12) through the patterned resist layer 512′, such that portions of the films/layers 508, 510 (referring to FIG. 12) uncovered by the patterned resist layer 512′ are removed. The remaining portions of the films/layers 508, 510 (referring to FIG. 12) form a variable resistance pattern 508′ and a top electrode 510′, respectively. Stated differently, through the photolithography process and the etching process, the films/layers 508, 510 (referring to FIG. 12) are patterned into the variable resistance patterns 508′ and the top electrode 510′, respectively. The one or more etching processes may include a dry etch using fluoride-based etchants, such as CF₄. In some other embodiments, the bottom electrode layer 506 may also be patterned through the etching process.

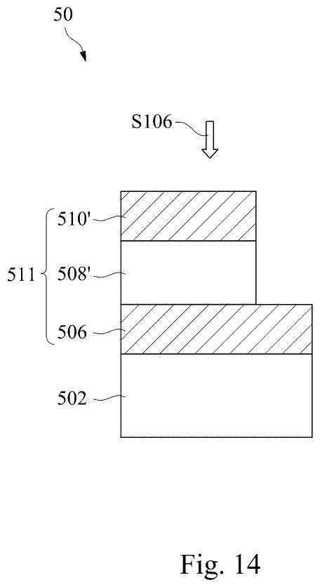

After the patterning process, an annealing process S106 may be performed to the resulting structure, as shown in FIG. 14. The bottom electrode layer 506, the variable resistance pattern 508′ and the top electrode 510′ constitute a capacitor 511 for storing memory data. The annealing process S106 can convert the variable resistance pattern 508′ from an amorphous structure to a crystal structure, such as a tetragonal phase. The annealing process S106 may include rapid thermal annealing (RTA) process, laser-spike annealing (LSA), furnace annealing, microwave annealing, flash annealing, the like, or the combination thereof. The memory cell 50 includes the bottom electrode layer 506, the variable resistance pattern 508′, and the top electrode 510′, respectively corresponding to the bottom electrode 104, the variable resistance pattern 106, and the top electrode 108 in FIG. 1. In some embodiments where the annealing process S106 is RTA process, the annealing process S106 is performed at a chamber pressure of about 0.001 atm to about 1 atm, under a temperature of about 300° C. to about 1000° C. by flowing gas non-reactive to the memory cell 50, such as N₂, Ar, He, Ne, Kr, Xe, Rn, the like, or a combination thereof in the chamber, and for a duration of about 1 s to about 10⁵ s. In some embodiments, an electric field cycling is applied to the memory cell 50 for improving properties of the memory cell 50 such as applying an electric field to the memory cell 50 in a range from about −20 MV/cm to about 20 MV/cm. In some embodiments, in the electric field cycling, an input pulse can be square-wave pulse, triangle-wave pulse, or sine wave pulse. In some embodiments, the electric filed cycling is performed for about one cycle to about 1010 cycles. In some embodiments, the variable resistance film 508 is formed using plasma-enhanced deposition such as plasma-enhanced ALD (PEALD) to improve properties of the memory cell 50. For example, the plasma is introduced during forming the variable resistance film 508. In some embodiments, before forming the variable resistance film 508, a plasma treatment is performed to a top surface of the bottom electrode layer 506 to enhance the properties of the memory cell 50. In some embodiments, after formation of the variable resistance film 508, a plasma treatment is performed to a top surface of the variable resistance film 508 to enhance the properties of the memory cell 50. In some embodiments, the memory cell 50 includes 1T1C configuration. In some other embodiments, the memory cell 50 includes 2TnC configuration, OTIC configuration, 0TnC configuration, nTnC configuration where ‘n’ can be a number in a range from 0 to 10. In these configurations, transistors can be planar field effect transistor (FET), nanowire FET, nanosheet-FET, FinFET, omega-FET, gate-all-around (GAA)-FET, oxide semiconductor transistor, or 2D FET. In some other embodiments, the memory cell 50 can store a variable amount of charge in a volatile manner by operating the memory cell 50 using a bias voltage in a range from about −20 MV/cm to about 20 MV/cm. In some other embodiments, the memory cell 50 can store a variable amount of charge in a non-volatile manner by operating the memory cell 50 using a bias voltage in a range from about −20 MV/cm to about 20 MV/cm. In some other embodiments, the operation range of the electric field of volatile manner and the operation range of the electric field of non-volatile manner can be separated or overlapped. In some other embodiments, the polarization operation range of non-volatile manner and the polarization operation range of volatile manner can be separated or overlapped. In some embodiments, the input voltage source that controls the volatile memory state and the non-volatile memory state can be the same or separated.

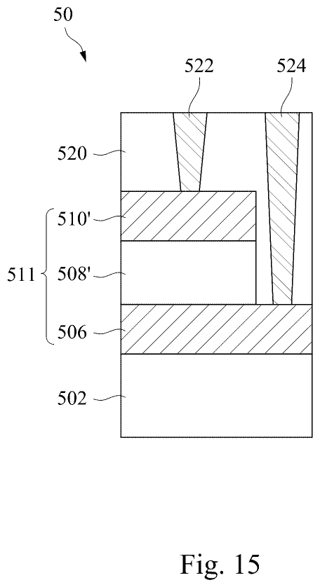

Reference is made to FIG. 15. In some embodiments, an inter-layer dielectric (ILD) layer 520 may be formed around the capacitor 511. The ILD layer 520 may be silicon oxide, fluorinated silica glass (FSG), carbon doped silicon oxide, tetra-ethyl-ortho-silicate (TEOS) oxide, phosphosilicate glass (PSG), borophosphosilicate glass (BPSG), Black Diamond® (Applied Materials of Santa Clara, Calif.), amorphous fluorinated carbon, low-k dielectric material, the like or combinations thereof. In some embodiments, a top electrode via 522 and a bottom electrode via 524 may be formed in the ILD layer 520, and landing on a top surface of the top electrode 510′ and a top surface of the bottom electrode layer 506, respectively. Formation of the top electrode via 522 and the bottom electrode via 524 may include etching openings in the ILD layer 520, and filling the openings with suitable conductive materials, followed by a planarization process (e.g., chemical mechanical polish (CMP) process). The top electrode via 522 and the bottom electrode via 524 may include suitable conductive materials, such as aluminum, aluminum alloy, copper, copper alloy, titanium, titanium nitride, tantalum, tantalum nitride, tungsten, cobalt, the like, and/or combinations thereof. In some other embodiments, the bottom electrode layer 506 may be electrically connected with underlying interconnect layers, and the bottom electrode via 524 may be omitted.

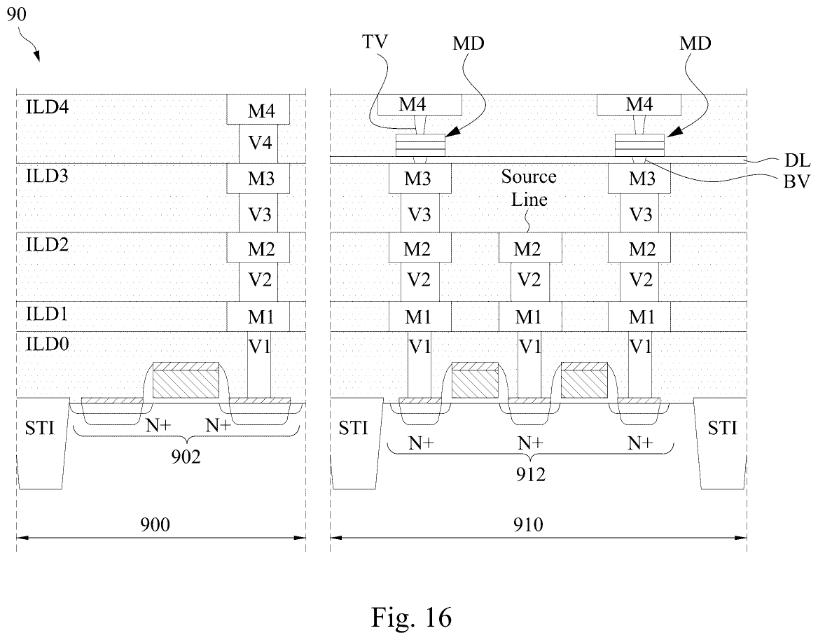

FIG. 16 is a schematic cross-sectional view of an integrated circuit device 90 having memory cells MD in accordance with some embodiments of the present disclosure. The integrated circuit device 90 includes a logic region 900 and a memory region 910. The logic region 900 may include circuitry, such as an exemplary logic transistor 902, for processing information received from the memory cell MD in the memory region 910 and for controlling reading and writing functions of the memory cell MD. In some embodiments, the memory cell MD may be similar to those shown above. In some embodiments, the memory cell MD is located on a bottom electrode via BV connected to underlying metallization layer. The formation of the bottom electrode via BV may include depositing a dielectric layer DL, etching an opening in the dielectric layer DL, and filling the opening with suitable conductive material, followed by a CMP process.

As depicted, the integrated circuit device 90 is fabricated using four metallization layers, labeled as M1 through M4, with four layers of metallization vias or interconnects, labeled as V1 through V4. Other embodiments may contain more or fewer metallization layers and a corresponding more or fewer number of vias. The logic region 900 includes a full metallization stack, including a portion of each of metallization layers M1-M4 connected by interconnects V2-V4, with V1 connecting the stack to a source/drain contact of the logic transistor 902. The memory region 910 includes a full metallization stack connecting the memory cell MD to transistors 912 in the memory region 910, and a partial metallization stack connecting a source line to the transistors 912 in the memory region 910. The memory cells MD are depicted as being fabricated in between the top of the M3 layer and the bottom of the M4 layer. In the illustrated embodiments, a top electrode via TV connects the top electrode TE to the M4 layer, and a bottom electrode via BV connects the bottom electrode BE to the M3 layer. Also included in semiconductor device is a plurality of ILD layers. Five ILD layers, identified as ILD0 through ILD4 are depicted as spanning the logic region 900 and the memory region 910. The ILD layers may provide electrical insulation as well as structural support for the various features of the semiconductor device during many fabrication process steps.

Based on the above discussions, it can be seen that the present disclosure offers advantages. It is understood, however, that other embodiments may offer additional advantages, and not all advantages are necessarily disclosed herein, and that no particular advantage is required for all embodiments. One advantage is that by using the first voltage sweep operation and the third voltage sweep operation, the memory cell can store the variable amount of charge in a volatile manner. Another advantage is that by using the second voltage sweep operation, the memory cell can store the variable amount of charge in a non-volatile manner. Such dual functionalities (i.e., volatile and non-volatile) of the single C-DRAM (i.e., one memory cell 10) can retain advantage of stable data retention of non-volatile memory (or FERAM) and advantage of rapid speed access of volatile memory (or AFERAM). Combination of the volatile and non-volatile memory within the single C-DRAM (i.e., one memory device) can eliminate data transmission latency and energy consumption between the main memory system (DRAM) and storage class memory (SCM) of the memory hierarchy.

In some embodiments, a method of operating a memory cell includes the following steps. A first voltage sweep operation is performed to the memory cell using a first voltage range. A second voltage sweep operation is performed to the memory cell using a second voltage range. A third voltage sweep operation is performed to the memory cell using a third voltage range, wherein the first voltage range, the second voltage range and the third voltage range are different from one another. In some embodiments, the first voltage range comprises a negative voltage. In some embodiments, the first voltage range is not positive. In some embodiments, the third voltage range comprises a positive voltage. In some embodiments, the third voltage range is not negative. In some embodiments, the second voltage range comprises a positive voltage and a negative voltage.

In some embodiments, a method of operating a memory cell comprising a top electrode, a variable resistance film and a bottom electrode stacked in sequence comprises the following steps. A first unipolar voltage sweep operation is performed to the memory cell. A first bipolar voltage sweep operation is performed to the memory cell. A second unipolar voltage sweep operation is performed to the memory cell.

In some embodiments, performing the first unipolar voltage sweep operation is performed such that the variable resistance film has a negative polarity. In some embodiments, performing the second unipolar voltage sweep operation is performed such that the variable resistance film has a positive polarity. In some embodiments, the method further comprises after performing the second unipolar voltage sweep operation to the memory cell, performing a second bipolar voltage sweep operation to the memory cell. In some embodiments, the method further comprises after performing the second unipolar voltage sweep operation to the memory cell, performing a third unipolar voltage sweep operation to the memory cell using a voltage range different from a voltage range of the second unipolar voltage sweep operation. In some embodiments, performing the first unipolar voltage sweep operation comprises applying a first voltage range to the memory cell, performing the second unipolar voltage sweep operation comprises applying a second voltage range to the memory cell, and the first voltage range non-overlaps the second voltage range. In some embodiments, performing the first bipolar voltage sweep operation comprises applying a third voltage range to the memory cell, and the third voltage range non-overlaps the first voltage range. In some embodiments, performing the first bipolar voltage sweep operation comprises applying a third voltage range to the memory cell, the third voltage range non-overlaps the second voltage range. In some embodiments, the variable resistance film comprises hafnium zirconium oxide (HZO). In some embodiments, the variable resistance film comprises Hf₁₋ₓZrₓO₂, in which x is greater than 50% and less than 100%.

In some embodiments, a method of operating a memory cell comprising a top electrode, a variable resistance film and a bottom electrode stacked in sequence, comprises the following steps. A first voltage sweep operation is performed to the memory cell such that the variable resistance film has a first polarization. A second voltage sweep operation is performed to the memory cell such that the variable resistance film has a second polarization. In some embodiments, a third voltage sweep operation is performed to the memory cell such that the variable resistance film has a third polarization, wherein the first polarization, the second polarization and the third polarization are different from one another in quantities. In some embodiments, the first polarization and the second polarization are negative. In some embodiments, the second polarization and the third polarization are positive. In some embodiments, the second polarization is positive.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A memory cell, comprising:
a substrate;
a bottom electrode over the substrate;
a variable resistance film over the bottom electrode; and
a top electrode over the variable resistance film, wherein the variable resistance film exhibits a first polarization in response to a first voltage sweep operation within a first voltage range, exhibits a second polarization in response to a second voltage sweep operation within a second voltage range, and exhibits a third polarization in response to a third voltage sweep operation within a third voltage range, wherein the first voltage range, the second voltage range, and the third voltage range are different from one another.

2. The memory cell of claim 1, wherein the first voltage range comprises a negative voltage.

3. The memory cell of claim 1, wherein the first voltage range is not positive.

4. The memory cell of claim 1, wherein the third voltage range comprises a positive voltage.

5. The memory cell of claim 1, wherein the third voltage range is not negative.

6. The memory cell of claim 1, wherein the second voltage range comprises a positive voltage and a negative voltage.

7. A memory cell, comprising:
a substrate;
a bottom electrode over the substrate;
a variable resistance film over the bottom electrode; and
a top electrode over the variable resistance film, wherein the variable resistance film exhibits a first polarization in response to a first voltage sweep operation applied to the memory cell, a second polarization in response to a second voltage sweep operation applied to the memory cell, and a third polarization in response to a third voltage sweep operation applied to the memory cell, with the first polarization, the second polarization, and the third polarization being different from one another in magnitude.

8. The memory cell of claim 7, wherein the first polarization and the second polarization are negative.

9. The memory cell of claim 7, wherein the second polarization and the third polarization are positive.

10. The memory cell of claim 7, wherein the second polarization is positive.

11. A method of operating a memory cell comprising a top electrode, a variable resistance film and a bottom electrode stacked in sequence, comprising:
performing a first unipolar voltage sweep operation to the memory cell;
performing a first bipolar voltage sweep operation to the memory cell; and
performing a second unipolar voltage sweep operation to the memory cell.

12. The method of claim 11, wherein performing the first unipolar voltage sweep operation is performed such that the variable resistance film has a negative polarity.

13. The method of claim 11, wherein performing the second unipolar voltage sweep operation is performed such that the variable resistance film has a positive polarity.

14. The method of claim 11, further comprising:
after performing the second unipolar voltage sweep operation to the memory cell, performing a second bipolar voltage sweep operation to the memory cell.

15. The method of claim 11, further comprising:
after performing the second unipolar voltage sweep operation to the memory cell, performing a third unipolar voltage sweep operation to the memory cell using a voltage range different from a voltage range of the second unipolar voltage sweep operation.

16. The method of claim 11, wherein performing the first unipolar voltage sweep operation comprises applying a first voltage range to the memory cell, performing the second unipolar voltage sweep operation comprises applying a second voltage range to the memory cell, and the first voltage range non-overlaps the second voltage range.

17. The method of claim 16, wherein performing the first bipolar voltage sweep operation comprises applying a third voltage range to the memory cell, and the third voltage range non-overlaps the first voltage range.

18. The method of claim 16, wherein performing the first bipolar voltage sweep operation comprises applying a third voltage range to the memory cell, the third voltage range non-overlaps the second voltage range.

19. The method of claim 16, wherein the variable resistance film comprises hafnium zirconium oxide (HZO).

20. The method of claim 16, wherein the variable resistance film comprises Hf₁₋ₓZrₓO₂, in which x is greater than 50% and less than 100%.
